(19) United States
(12) Patent Application Publication
(10) Pub. No.: US 2025/0084530 A1
(43) Pub. Date: Mar. 13, 2025

(54) FILM-FORMING METHOD AND FILM-FORMING APPARATUS

(71) Applicant: Tokyo Electron Limited, Tokyo (JP)

(72) Inventors: Yohei MATSUYAMA, Yamanashi (JP); Ken OKOSHI, Yamanashi (JP); Yuki KIKUCHI, Yamanashi (JP)

(21) Appl. No.: 18/819,238

(22) Filed: Aug. 29, 2024

(30) Foreign Application Priority Data
Sep. 12, 2023 (JP) 2023-147603

(51) Int. Cl. C23C 16/34; C23C 16/455; C23C 16/52; H01J 37/32; H01L 21/02

(52) U.S. Cl. CPC C23C 16/345; C23C 16/342; C23C 16/45538; C23C 16/45542; C23C 16/45544; C23C 16/45553; C23C 16/52; H01J 37/3244; H01L 21/0217; H01L 21/02211; H01L 21/02274; H01L 21/0228; H01J 2237/332

(57) ABSTRACT

A film-forming method according to an aspect of the present disclosure forms a film containing a silicon atom and a nitrogen atom on a surface of a substrate including a metal film at the surface of the substrate. The film-forming method includes: supplying a boron-containing gas and a first nitriding gas to the substrate, thereby forming a first film on the surface, the first film containing a boron atom and a nitrogen atom; and supplying a silicon-containing gas and a second nitriding gas to the substrate, thereby forming a second film on the first film, the second film containing a silicon atom and a nitrogen atom.

### CROSS-REFERENCE TO RELATED APPLICATIONS

This application is based upon and claims priority to Japanese Patent Application No. 2023-147603, filed on Sep. 12, 2023, the entire contents of which are incorporated herein by reference.

### BACKGROUND

### 1. Field of the Invention

The present disclosure relates to film-forming methods and film-forming apparatuses.

### 2. Description of the Related Art

A method of forming a silicon oxide film on a tungsten film through atomic layer deposition (ALD) using a silicon-containing gas and an oxygen active species, is known (see, for example, Japanese Unexamined Patent Publication No. 2019-29582). According to the method disclosed in Japanese Unexamined Patent Publication No. 2019-29582, a first silicon oxide film is formed through film formation at a low temperature of from 25° C. (degrees Celsius) through 350° C., and then a second silicon oxide film is formed through film formation at a medium to high temperature of from 500° C. through 750° C., thereby suppressing oxidation of the tungsten film.

### SUMMARY

A film-forming method according to an aspect of the present disclosure forms a film containing a silicon atom and a nitrogen atom on a surface of a substrate including a metal film at the surface of the substrate. The film-forming method includes: supplying a boron-containing gas and a first nitriding gas to the substrate, thereby forming a first film on the surface, the first film containing a boron atom and a nitrogen atom; and supplying a silicon-containing gas and a second nitriding gas to the substrate, thereby forming a second film on the first film, the second film containing a silicon atom and a nitrogen atom.

### BRIEF DESCRIPTION OF THE DRAWINGS

FIG. 1 is a flowchart illustrating a film-forming method according to an embodiment of the present disclosure;

FIG. 2A is a cross-sectional view illustrating the film-forming method according to the embodiment;

FIG. 2B is a cross-sectional view illustrating the film-forming method according to the embodiment;

FIG. 2C is a cross-sectional view illustrating the film-forming method according to the embodiment;

FIG. 3 is a flowchart illustrating an example of a process for forming a BN film;

FIG. 4 is a flowchart illustrating another example of the process for forming the BN film;

FIG. 5 is a vertical cross-sectional view illustrating a film-forming apparatus according to an embodiment of the present disclosure;

FIG. 6 is a horizontal cross-sectional view illustrating the film-forming apparatus according to the embodiment; and

FIG. 7 is a graph illustrating measurement results of the sheet resistance of a Ru film.

### DETAILED DESCRIPTION OF THE PRESENT DISCLOSURE

The present disclosure provides a technique that is able to successfully achieve both suppression of an increase in the resistivity of a metal film and improvement in productivity when forming a film containing a silicon atom and a nitrogen atom on a metal film.

Hereinafter, non-limiting illustrative embodiments of the present disclosure will be described with reference to the attached drawings. In all of the attached drawings, the same or corresponding members or parts are denoted by the same or corresponding reference symbols, and redundant description thereof is omitted.

### [Film-Forming Method]

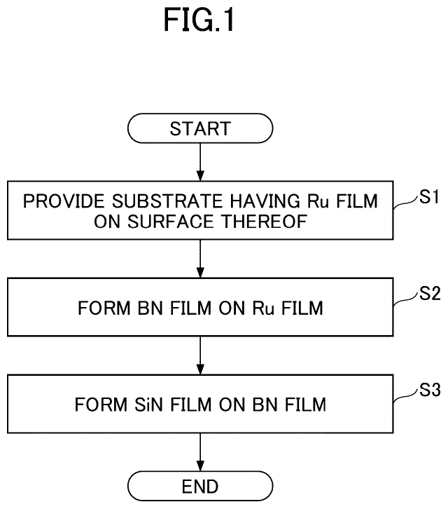

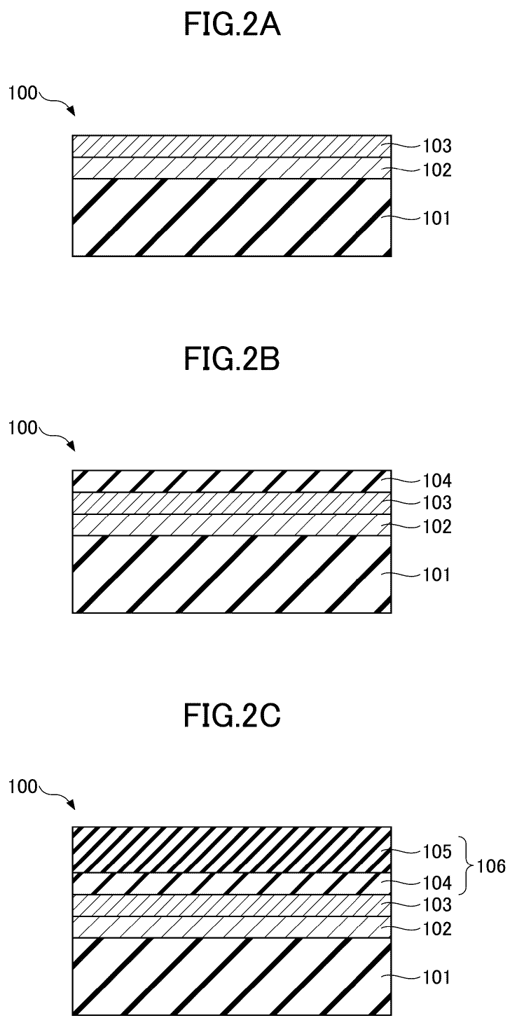

The film-forming method according to the embodiment of the present disclosure will be described with reference to FIGS. 1 and 2. FIG. 1 is a flowchart illustrating the film-forming method according to the embodiment. FIGS. 2A to 2C are cross-sectional views illustrating the film-forming method according to the embodiment. The following describes the embodiment taking, as an example, a case in which a boron nitride (BN) film and a silicon nitride (SiN) film are formed in this order on a ruthenium (Ru) film. The Ru film is an example of the metal film. The BN film is an example of the first film containing a boron (B) atom and a nitrogen (N) atom. The SiN film is an example of the second film containing a silicon (Si) atom and a nitrogen atom.

In step S1, as illustrated in FIG. 2A, a substrate 100 is provided. The substrate 100 includes an insulating film 101, a barrier metal film 102, and a Ru film 103. The insulating film 101 is, for example, a thermal oxide film. The barrier metal film 102 is provided on the insulating film 101. The barrier metal film 102 is, for example, a titanium nitride (TiN) film. The Ru film 103 is provided on the barrier metal film 102. The Ru film 103 is formed, for example, through physical vapor deposition (PVD). The Ru film 103 may be thermally treated, for example, in a pressure-reduced atmosphere or an inert gas atmosphere that is maintained at 600° C. or higher and 700° C. or lower. In this case, the crystal particle diameter (grain size) of the Ru film 103 can be increased to reduce the resistivity.

Step S2 is performed after step S1. In step S2, as illustrated in FIG. 2B, a BN film 104 is formed on the Ru film 103 in a state the temperature of the substrate 100 is maintained at a first temperature. The first temperature is, for example, 550° C. or higher and 650° C. or lower. The BN film 104 can be formed, for example, through thermal ALD in which supply of the boron-containing gas to the substrate 100 and supply of the first nitriding gas to the substrate 100 are alternately repeated. In this case, the BN film 104 is readily formed conformally along the surface of the Ru film 103. The boron-containing gas is a gas that contains a boron atom and is free of a silicon atom. The boron-containing gas is, for example, a diborane (B₂H₆) gas or a boron trichloride (BCl₃) gas. The first nitriding gas is, for example, an ammonia (NH₃) gas. The thickness of the BN film 104 is, for example, 1 nm (nanometer) or greater. In this case, even if the Ru film 103 is exposed to the silicon-containing gas at the first temperature in step S3, the Ru film 103 is not appreciably silicided.

Step S3 is performed after step S2. In step S3, as illustrated in FIG. 2C, a SiN film 105 is formed on the BN film 104 in a state in which the temperature of the substrate 100 is maintained at the first temperature. The SiN film 105 can be formed, for example, through plasma ALD in which supply of the silicon-containing gas to the substrate 100 and exposure of the substrate 100 to a plasma generated from the second nitriding gas are alternately repeated. In this case, the high-quality SiN film 105 can be formed conformally along the surface of the BN film 104. The silicon-containing gas is, for example, a dichlorosilane (DCS) gas. The second nitriding gas is, for example, the same gas as the first nitriding gas. The second nitriding gas is, for example, an ammonia gas.

Through steps S1 to S3 described above, it is possible to form a stacked film 106 in which the BN film 104 and the SiN film 105 are stacked on the Ru film 103 in this order.

When the SiN film 105 is formed on the Ru film 103 at a high temperature (e.g., 550° C. or higher), silicon (Si) atoms contained in the silicon-containing gas are diffused into the Ru film 103, and a ruthenium silicide (RuSi) layer is formed in the Ru film 103. When the RuSi layer is formed in the Ru film 103, the Ru film 103 has an increased resistance.

According to the film-forming method according to the embodiment, the BN film 104 is formed on the Ru film 103, and the SiN film 105 is formed on the BN film 104. The boron-containing gas used for forming the BN film 104 is free of a silicon atom. Therefore, even if the surface of the Ru film 103 is exposed in forming the BN film 104, the Ru film 103 is not silicided. Because the surface of the Ru film 103 is covered by the BN film 104 in forming the SiN film 105, the surface of the Ru film 103 is not exposed to the silicon-containing gas. Therefore, the silicidation of the Ru film 103 can be suppressed. As a result, an increase in the resistivity of the Ru film 103 can be suppressed. According to the film-forming method according to the embodiment, the BN film 104 can be formed at the same temperature as that at which the SiN film 105 is formed, and thus the BN film 104 and the SiN film 105 can be successively formed without changing the temperature, resulting in increased productivity. As described above, according to the film-forming method according to the embodiment, when the SiN film 105 is formed on the Ru film 103, both the suppression of the increase in the resistivity of the Ru film 103 and the improvement in productivity can be successfully achieved.

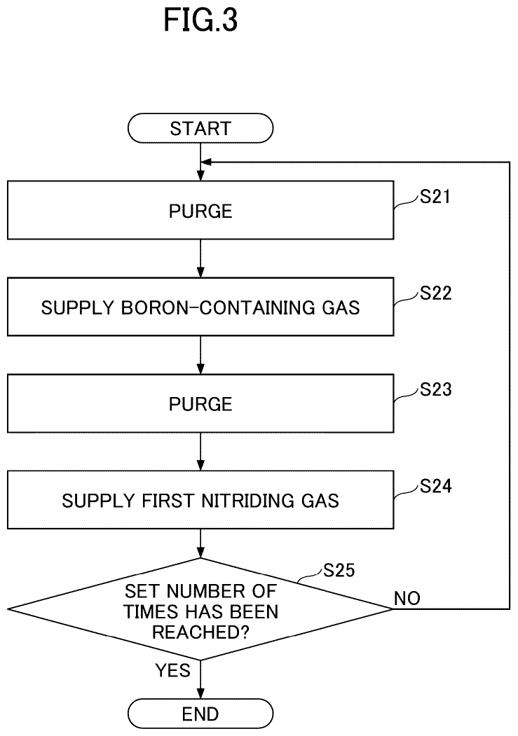

An example of the method of forming the BN film 104 in step S2 will be described with reference to FIG. 3. FIG. 3 is a flowchart illustrating an example of the process for forming the BN film 104.

When the process illustrated in FIG. 3 is started, a purge gas is supplied in step S21. Thereby, the surface of the substrate 100 is purged with the purge gas, and excess gas molecules attached to the surface of the substrate 100 are removed. The purge gas may be, for example, an argon (Ar) gas, a nitrogen (N—) gas, or a gas mixture of an argon gas and a nitrogen gas.

After a predetermined time passes from the start of step S21, the supply of the purge gas is stopped. Then, in step S22, a boron-containing gas is supplied. Thereby, the boron-containing gas is adsorbed on the substrate 100.

After a predetermined time passes from the start of step S22, the supply of the boron-containing gas is stopped. Then, in step S23, a purge gas is supplied. Thereby, the surface of the substrate 100 is purged with the purge gas, and excess gas molecules attached to the surface of the substrate 100 are removed.

After a predetermined time passes from the start of step S23, the supply of the purge gas is stopped. Then, in step S24, a first nitriding gas is supplied. Thereby, the boron-containing gas adsorbed on the substrate 100 reacts with the first nitriding gas and is nitrided.

After a predetermined time passes from the start of step S24, it is determined in step S25 whether or not the process of steps S21 to S24 has been performed a set number of times. When it is determined that the process of steps S21 to S24 has not been performed the set number of times, the process returns to step S21, and the process of steps S21 to S24 is performed again. When it is determined that the process of steps S21 to S24 has been performed the set number of times, the process of FIG. 3 is ended.

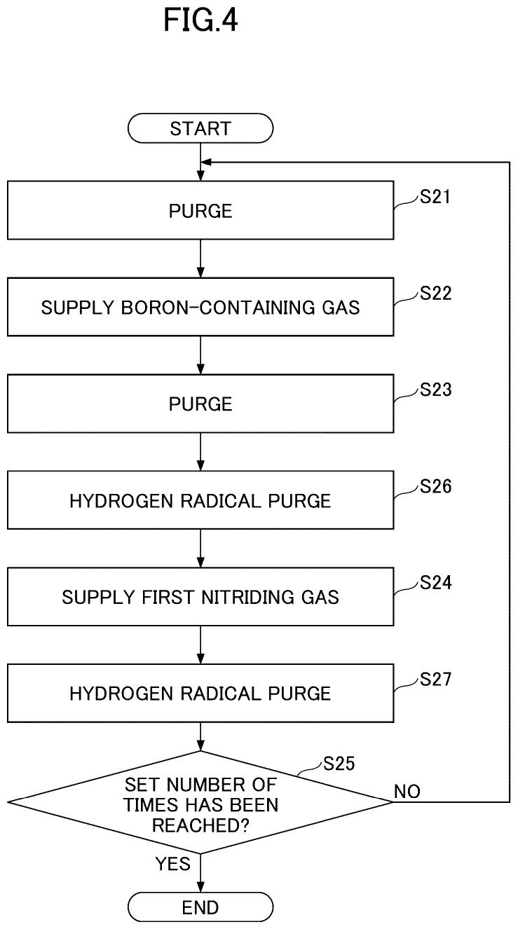

Another example of the method of forming the BN film 104 in step S2 will be described with reference to FIG. 4. FIG. 4 is a flowchart illustrating another example of the process for forming the BN film 104.

The process of FIG. 4 is different from the process of FIG. 3 in that hydrogen radical purge (HRP) is performed between steps S23 and S24 and between steps S24 and S25. The other configurations are the same as those of the process of FIG. 3. In the following, the configurations different from those of the process of FIG. 3 will be mainly described.

First, similar to the process of FIG. 3, steps S21 to S23 are performed. After a predetermined time passes from the start of step S23, the supply of the purge gas is stopped. Then, in step S26, hydrogen radical purge is performed. In the hydrogen radical purge, a hydrogen (H) gas is converted into a plasma, thereby generating hydrogen radicals. The hydrogen radicals react with halogen or the like that can be contained in the boron-containing gas adsorbed on the surface of the Ru film 103. The halogen or the like is replaced with hydrogen, thereby modifying the boron-containing film.

After a predetermined time passes from the start of step S26, the hydrogen radical purge is stopped. Then, in step S24, a first nitriding gas is supplied. Thereby, the boron-containing gas adsorbed on the substrate 100 reacts with the first nitriding gas and is nitrided.

After a predetermined time passes from the start of step S24, the supply of the first nitriding gas is stopped. Then, in step S27, the hydrogen radical purge is performed. In the hydrogen radical purge, a hydrogen gas is converted into a plasma, thereby generating hydrogen radicals. The hydrogen radicals react with halogen or the like that can be contained in the BN film 104 formed on the surface of the Ru film 103. The halogen or the like is replaced with hydrogen, thereby modifying the BN film 104. Through the above process, the BN film 104 having a favorable film quality can be formed.

After a predetermined time passes from the start of step S24, it is determined in step S25 whether or not the process of steps S21, S22, S23, S26, S24, and S27 has been performed a set number of times. When it is determined that the process of steps S21, S22, S23, S26, S24, and S27 has not been performed the set number of times, the process returns to step S21, and the process of steps S21, S22, S23, S26, S24, and S27 is performed again. When it is determined that the process of steps S21, S22, S23, S26, S24, and S27 has been performed the set number of times, the process of FIG. 4 is ended.

### [Film-Forming Apparatus]

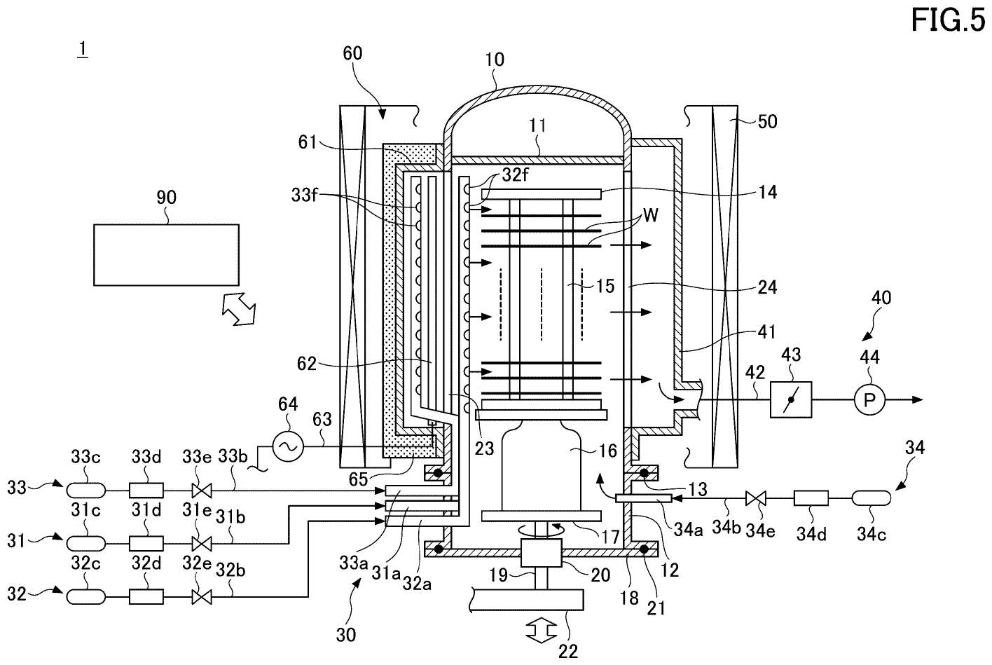

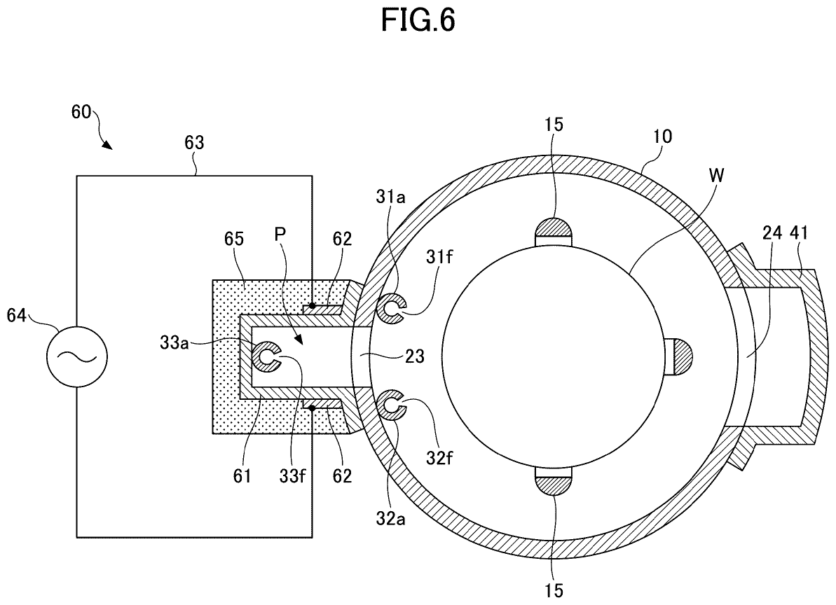

A film-forming apparatus 1 according to an embodiment of the present disclosure will be described with reference to FIGS. 5 and 6. FIG. 5 is a vertical cross-sectional view illustrating the film-forming apparatus 1 according to the embodiment. FIG. 6 is a horizontal cross-sectional view illustrating the film-forming apparatus 1 according to the embodiment.

The film-forming apparatus 1 includes a process chamber 10, a gas supply 30, an exhauster 40, a heater 50, a plasma generator 60, and a controller 90.

The process chamber 10 has a vertical cylindrical shape with a ceiling having an open lower end. The process chamber 10 is formed of quartz or the like. A ceiling plate 11 formed of quartz is provided near the upper end of the process chamber 10, thereby sealing the region below the ceiling plate 11. A manifold 12 formed in a cylindrical shape is connected to the opening at the lower end of the process chamber 10 via a sealing member 13, such as an O-ring or the like. The manifold 12 is formed of a metal or the like.

The manifold 12 supports the lower end of the process chamber 10. A boat 14 is inserted into the process chamber 10 from below the manifold 12. The boat 14 retains a plurality of substrates W disposed at intervals along the vertical direction. The boat 14 retains the substrates W so as to be horizontal. The boat 14 is formed of quartz or the like. The boat 14 includes, for example, three struts 15. Each of the struts 15 is provided with unillustrated grooves formed at predetermined intervals along the vertical direction. The boat 14 retains the substrates W at the grooves. The substrate W is a semiconductor wafer or the like.

The boat 14 is placed on a table 17 via a heat-insulating cylinder 16 formed of quartz. The table 17 is supported on a rotation shaft 19 penetrating through a cover 18. The cover 18 performs opening and closing of the opening at the lower end of the manifold 12. The cover 18 is formed of stainless steel or the like.

A magnetic fluid seal 20 is provided at the penetrating portion of the rotation shaft 19. The magnetic fluid seal 20 airtightly seals and rotatably supports the rotation shaft 19. A sealing 21 is provided between the peripheral portion of the cover 18 and the lower end of the manifold 12. The sealing 21 maintains the airtightness of the process chamber 10. The sealing 21 is an O-ring or the like.

The rotation shaft 19 is attached to the end of an arm 22 supported by an unillustrated raising and lowering mechanism, such as a boat elevator or the like. Thereby, the boat 14 and the cover 18 are integrally raised and lowered, and are inserted into and removed from the process chamber 10.

The side wall of the process chamber 10 is provided with an opening 23 and an exhaust port 24. The opening 23 is formed in a vertically elongated shape so as to vertically cover all of the substrates W supported by the boat 14. The exhaust port 24 is provided, for example, at a position facing the opening 23. The exhaust port 24 is formed in a vertically elongated shape so as to vertically cover all of the substrates W supported by the boat 14.

The gas supply 30 can introduce various processing gases used in the above-described film-forming method into the process chamber 10. The gas supply 30 includes a boron supply 31, a DCS supply 32, an ammonia supply 33, and a nitrogen supply 34.

The boron supply 31 includes: a boron supply tube 31a within the process chamber 10; and a boron supply path 31b external of the process chamber 10. The boron supply path 31b is provided with a boron supply source 31c, a mass flow controller 31d, and a valve 31e that are arranged in this order from upstream to downstream in the gas flowing direction. Thereby, the boron-containing gas of the boron supply source 31c is controlled by the valve 31e in terms of the timing of supply, and is adjusted to a predetermined flow rate by the mass flow controller 31d. The boron-containing gas flows into the boron supply tube 31a from the boron supply path 31b, and is discharged into the process chamber 10 from the boron supply tube 31a.

The DCS supply 32 includes: a DCS supply tube 32a within the process chamber 10; and a DCS supply path 32b external of the process chamber 10. The DCS supply path 32b is provided with a DCS source 32c, a mass flow controller 32d, and a valve 32e that are arranged in this order from upstream to downstream in the gas flowing direction. Thereby, the DCS gas of the DCS source 32c is controlled by the valve 32e in terms of the timing of supply, and is adjusted to a predetermined flow rate by the mass flow controller 32d. The DCS gas flows into the DCS supply tube 32a from the DCS supply path 32b, and is discharged into the process chamber 10 from the DCS supply tube 32a.

The ammonia supply 33 includes: an ammonia supply tube 33a within the process chamber 10; and an ammonia supply path 33b external of the process chamber 10. The ammonia supply path 33b is provided with an ammonia source 33c, a mass flow controller 33d, and a valve 33e that are arranged in this order from upstream to downstream in the gas flowing direction. Thereby, the ammonia gas of the ammonia source 33c is controlled by the valve 33e in terms of the timing of supply, and is adjusted to a predetermined flow rate by the mass flow controller 33d. The ammonia gas flows into the ammonia supply tube 33a from the ammonia supply path 33b, and is discharged into the process chamber 10 from the ammonia supply tube 33a.

The nitrogen supply 34 includes: a nitrogen supply tube 34a within the process chamber 10; and a nitrogen supply path 34b external of the process chamber 10. The nitrogen supply path 34b is provided with a nitrogen source 34c, a mass flow controller 34d, and a valve 34e that are arranged in this order from upstream to downstream in the gas flowing direction. Thereby, the nitrogen gas of the nitrogen source 34c is controlled by the valve 34e in terms of the timing of supply, and is adjusted to a predetermined flow rate by the mass flow controller 34d. The nitrogen gas flows into the nitrogen supply tube 34a from the nitrogen supply path 34b, and is discharged into the process chamber 10 from the nitrogen supply tube 34a.

The boron supply tube 31a and the DCS supply tube 32a extend vertically along the inner wall of the process chamber 10. The base ends of the boron supply tube 31a and the DCS supply tube 32a are bent in an L shape and extend horizontally, and are supported so as to penetrate through the manifold 12. A plurality of boron discharge ports 31f are provided at portions of the boron supply tube 31a located within the process chamber 10. A plurality of DCS discharge ports 32f are provided at portions of the DCS supply tube 32a located within the process chamber 10.

The ammonia supply tube 33a extends vertically along a plasma partition wall 61 in a plasma generation space P described below. The base end of the ammonia supply tube 33a is bent in an L shape and extends horizontally, and is supported so as to penetrate through the manifold 12. A plurality of ammonia discharge ports 33f are provided at portions of the ammonia supply tube 33a located within the process chamber 10.

The nitrogen supply tube 34a extends horizontally within the process chamber 10, and is supported so as to penetrate through the side wall of the manifold 12. The nitrogen supply tube 34a has an opening at the tip end thereof, and the nitrogen gas is discharged from the opening.

The boron supply tube 31a, the DCS supply tube 32a, the ammonia supply tube 33a, and the nitrogen supply tube 34a are formed of quartz or the like.

The respective discharge ports (the boron discharge ports 31f, the DCS discharge ports 32f, and the ammonia discharge ports 33f) are formed at predetermined intervals along the extending direction of the respective gas supply tubes (the boron supply tube 31a, the DCS supply tube 32a, and the ammonia supply tube 33a). The respective discharge ports discharge gas in the horizontal direction. The interval between the discharge ports is, for example, set to be the same as the interval between the substrates W retained by the boat 14. The position of each of the discharge ports in the height direction is set to an intermediate position between the substrates W next to each other in the vertical direction. Thereby, the discharge port can efficiently supply gas to the facing surfaces between the substrates W next to each other.

The gas supply 30 may mix a plurality of types of gases with each other, and discharge the gas mixture from a single gas supply tube. The respective gas supply tubes (the boron supply tube 31a, the DCS supply tube 32a, the ammonia supply tube 33a, and the nitrogen supply tube 34a) may have different shapes or arrangements. The gas supply 30 may include a supply configured to supply another gas that is different from the boron-containing gas, the DCS gas, and the ammonia gas.

The exhauster 40 includes a cover 41, an exhaust tube 42, a pressure control valve 43, and a vacuum pump 44. The cover 41 is attached to a portion corresponding to the exhaust port 24 of the process chamber 10 so as to cover the exhaust port 24. The cover 41 extends vertically along the outer wall of the process chamber 10. The exhaust tube 42 is connected to the lower portion of the cover 41. The pressure control valve 43 and the vacuum pump 44 are provided in the exhaust tube 42. The pressure control valve 43 controls the internal pressure of the process chamber 10. The vacuum pump 44 exhausts the interior of the process chamber 10.

The heater 50 is provided around the process chamber 10. The heater 50 includes a heat generator or the like. The heater is configured to be controlled in terms of output, thereby heating the substrates W within the process chamber 10 to a predetermined temperature.

The plasma generator 60 is provided at a part of the side wall of the process chamber 10. The plasma generator 60 is configured to generate a plasma from an ammonia gas supplied by the ammonia supply tube 33a. The plasma generator 60 includes the plasma partition wall 61, a pair of plasma electrodes 62, a power supply line 63, an RF power supply 64, and an insulating protective cover 65.

The plasma partition wall 61 is airtightly welded to the outer wall of the process chamber 10. The plasma partition wall 61 is formed of quartz or the like. The plasma partition wall 61 has a recessed shape in a horizontal cross section. The plasma partition wall 61 covers the opening 23. The plasma partition wall 61 forms the plasma generation space P that is in communication with the interior of the process chamber 10.

The pair of plasma electrodes 62 each have a vertically elongated shape. The pair of plasma electrodes 62 are provided on the outer surfaces of the facing portions of the plasma partition wall 61. The pair of plasma electrodes 62 are arranged to face each other across the facing portions of the plasma partition wall 61 and the plasma generation space P. The power supply line 63 is connected to the lower end of each of the plasma electrodes 62.

The power supply line 63 electrically connects the plasma electrodes 62 and the RF power supply 64. For example, one end of the power supply line 63 is connected to the lower end of each of the plasma electrodes 62, and the other end thereof is connected to the RF power supply 64.

The RF power supply 64 is connected to the lower end of the plasma electrodes 62 via the power supply line 63. The RF power supply 64 is configured to supply an RF power of 13.56 MHz or the like to the pair of plasma electrodes 62. Thereby, the RF power is applied to the plasma generation space P, and a plasma is generated from the ammonia gas supplied to the plasma generation space P.

The insulating protective cover 65 is attached to the exterior of the plasma partition wall 61 so as to cover the plasma partition wall 61. An unillustrated coolant path may be provided in the inner portion of the insulating protective cover 65. In this case, the plasma electrode 62 can be cooled by flowing a coolant through the coolant path.

The controller 90 is configured to control the operations of the components of the film-forming apparatus 1. The controller 90 may be a computer or the like. A program for the computer configured to control the operations of the components of the film-forming apparatus 1 is stored in a storage medium. The storage medium may be a flexible disk, a compact disk, a hard disk, a flash memory, a DVD, or the like.

### [How the Film-Forming Apparatus Works]

An example of how the film-forming apparatus 1 works when performing the film-forming method according to the embodiment will be described.

First, the controller 90 controls an unillustrated raising and lowering mechanism, thereby transferring the boat 14 retaining the substrates W into the process chamber 10, and airtightly closing the opening at the lower end of the process chamber 10 by the cover 18. Thereby, the substrates W are stored in the process chamber 10. Subsequently, the controller 90 controls the exhauster 40 to reduce the internal pressure of the process chamber 10. Further, the controller 90 controls the heater 50 to adjust the temperature of the substrates W to a first temperature. Each of the substrates W may be the substrate 100 described above (step S1 in FIG. 1).

Next, the controller 90 controls the heater 50 to maintain the temperature of the substrates W at the first temperature, and in this state, controls the gas supply 30 to repeatedly supply the boron-containing gas and the ammonia gas alternately into the process chamber 10. Thereby, the BN film 104 is formed on the Ru film 103 through thermal ALD (step S2 in FIG. 1).

Next, the controller 90 controls the heater 50 to maintain the temperature of the substrates W at the first temperature, and in this state, controls the gas supply 30 to repeatedly supply the DCS gas and the ammonia gas alternately into the process chamber 10. Also, when the ammonia gas is supplied into the process chamber 10, the controller 90 controls the RF power supply 64 to supply an RF power of 13.56 MHz or the like to the pair of plasma electrodes 62, thereby generating a plasma from the ammonia gas. Thereby, the SiN film 105 is formed on the BN film 104 through plasma ALD (step S3 in FIG. 1).

Next, the controller 90 raises the internal pressure of the process chamber 10 to the atmospheric pressure, and reduces the internal temperature of the process chamber 10 to a temperature at which the boat 14 is to be removed. Subsequently, the controller 90 controls the raising and lowering mechanism to transfer the boat 14 from the interior of the process chamber 10. Through the above procedure, the stacked film 106, in which the BN film 104 and the SiN film 105 are stacked in this order, can be formed on the plurality of substrates W retained by the boat 14.

### EXAMPLES

First, five substrates W1 to W5 having Ru films on surfaces thereof were provided. Subsequently, the sheet resistance of the Ru film of each of the substrates W1 to W5 was measured. Subsequently, various films were formed on the Ru films of the substrates W1 to W5 in the process chamber 10 of the film-forming apparatus 1. The various films are described below. After the various films were formed, the sheet resistance of the Ru film of each of the substrates W1 to W5 was measured again.

For the substrate W1, a 2 nm-thick SiN film was formed on the Ru film through plasma ALD without forming a BN film. The SiN film was formed under conditions B1 below.

For the substrate W2, a 2 nm-thick BN film was formed on the Ru film through thermal ALD. The BN film was formed under conditions A1 below.

For the substrate W3, a 1 nm-thick BN film was formed on the Ru film through thermal ALD, and a 1 nm-thick SiN film was formed on the BN film through plasma ALD. The BN film was formed under the conditions A1 below, and the SiN film was formed under the conditions B1 below.

For the substrate W4, a 2 nm-thick BN film was formed on the Ru film through thermal ALD. The BN film was formed under conditions A2 below.

For the substrate W5, a 1 nm-thick BN film was formed on the Ru film through thermal ALD, and a 1 nm-thick SiN film was formed on the BN film through plasma ALD. The BN film was formed under the conditions A2 below, and the SiN film was formed under the conditions B1 below.

### (Conditions for Forming the BN Film: Conditions A1)

Substrate temperature: 630° C.
Gas supply sequence: repetition of (purge→boron-containing gas→purge→ammonia gas)

### (Conditions for Forming the BN Film: Conditions A2)

Substrate temperature: 630° C.
Gas supply sequence: repetition of (purge→boron-containing gas→purge→hydrogen radical purge→ammonia gas→hydrogen radical purge)

### (Conditions for Forming the SiN Film: Conditions B1)

Substrate temperature: 630° C.
Gas supply sequence: repetition of (purge→DCS gas→purge→ammonia plasma)

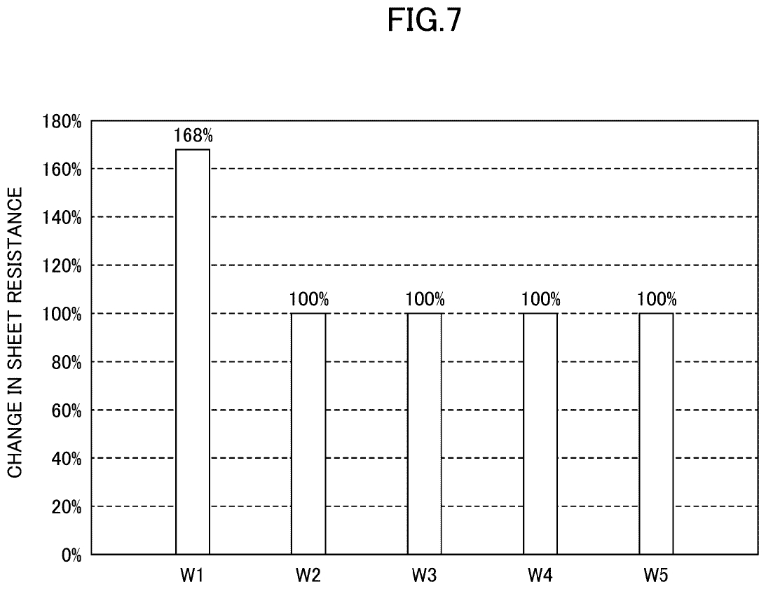

FIG. 7 is a graph illustrating measurement results of the sheet resistance of the Ru film. The sheet resistance of the Ru film illustrated in FIG. 7 is a relative value when the sheet resistance of the Ru films before the formation of the various films on the Ru films is 100%. The bars in the graph of FIG. 7 illustrate the results of the substrate W1, the substrate W2, the substrate W3, the substrate W4, and the substrate W5 from left to right.

As illustrated in FIG. 7, the relative value of the sheet resistance of the Ru film is 168% for the substrate W1, and is 100% for the substrates W2 to W5. This result indicates that the sheet resistance of the Ru film increases when the SiN film is formed without forming the BN film on the Ru film, whereas the increase in the sheet resistance of the Ru film is suppressed when the SiN film is formed after the formation of the BN film on the Ru film. This is because, conceivably, the Ru film is silicided when the BN film is not formed on the Ru film, whereas when the BN film is formed on the Ru film, the BN film functions as a barrier film for preventing the silicidation of the Ru film.

The embodiments disclosed herein should be construed to be illustrative and non-limiting in all respects. Omissions, substitutions, or modifications can be made to the above embodiments in various forms without departing from the scope of the claims as recited.

In the above-described embodiments, the silicon-containing gas is a DCS gas. However, the present disclosure is not limited thereto. For example, the silicon-containing gas can be selected from a monochlorosilane gas, a dichlorosilane gas, a trichlorosilane gas, a hexachlorodisilane gas, a trisilylamine gas, or combinations thereof.

In the above-described embodiments, the first nitriding gas and the second nitriding gas are an ammonia gas. However, the present disclosure is not limited thereto. For example, the first nitriding gas and the second nitriding gas may be different gases. For example, the first nitriding gas and the second nitriding gas may be an ammonia (NH₃) gas, a diazene (N₂H₂) gas, a hydrazine (N₂H₄) gas, a monomethylhydrazine (CH₃(NH)NH₂) gas, or combinations thereof.

In the above-described embodiments, the metal film is a Ru film. The present disclosure is not limited thereto. For example, the metal film may be a tungsten film, a cobalt film, or a molybdenum film.

In the above-described embodiment, the first film containing the boron atom and the nitrogen atom is a BN film. However, the present disclosure is not limited thereto. For example, the first film may contain another element in addition to the boron atom and the nitrogen atom.

In the above-described embodiment, the second film containing the silicon atom and the nitrogen atom is a SiN film. However, the present disclosure is not limited thereto. For example, the second film may contain another element in addition to the silicon atom and the nitrogen atom. For example, the second film may be a Low-k film, such as a SiCN film, a SiON film, a SiOCN film, a SiBN film, a SiBCN film, or the like.

In the above-described embodiment, the BN film is formed through thermal ALD. However, the present disclosure is not limited thereto. For example, the BN film may be formed through plasma ALD. However, in view that the surface roughness of the BN film can be reduced, thermal ALD is preferable. For example, the BN film may be formed through chemical vapor deposition (CVD). The CVD may be thermal CVD or plasma CVD.

In the above-described embodiment, the SiN film is formed through plasma ALD. However, the present disclosure is not limited thereto. For example, the SiN film may be formed through thermal ALD. For example, the SiN film may be formed through CVD. The CVD may be thermal CVD or plasma CVD.

In the above-described embodiment, the film-forming apparatus is a capacitively coupled plasma (CCP) apparatus. However, the present disclosure is not limited thereto. For example, the film-forming apparatus may be an inductively coupled plasma (ICP) apparatus, a remote plasma apparatus, or a microwave plasma apparatus.

In the above-described embodiment, the film-forming apparatus is a batch-type apparatus configured to process a plurality of substrates at one time. However, the present disclosure is not limited thereto. For example, the film-forming apparatus may be a semi-batch-type apparatus configured to process a plurality of substrates arranged on a rotation table within a process chamber by rotating the rotation table to allow the substrates to pass through a plurality of processing regions sequentially. For example, the film-forming apparatus may be a single-wafer type apparatus configured to process the substrates one by one.

According to the present disclosure, when forming the film containing the silicon atom and the nitrogen atom on the metal film, it is possible to successfully achieve both the suppression of the increase in the resistivity of the metal film and the improvement in the productivity.

What is claimed is:

1. A film-forming method for forming a film containing a silicon atom and a nitrogen atom on a surface of a substrate including a metal film at the surface of the substrate, the film-forming method comprising:
a) supplying a boron-containing gas and a first nitriding gas to the substrate, thereby forming a first film on the surface, the first film containing a boron atom and a nitrogen atom; and
b) supplying a silicon-containing gas and a second nitriding gas to the substrate, thereby forming a second film on the first film, the second film containing a silicon atom and a nitrogen atom.

2. The film-forming method according to claim 1, wherein,
a) is performed in a state in which the substrate is maintained at a first temperature, and
b) is performed in a state in which the substrate is maintained at the first temperature.

3. The film-forming method according to claim 2, wherein,
the first temperature is 550° C. or higher and 650° C. or lower.

4. The film-forming method according to claim 1, wherein,
a) includes forming the first film through thermal atomic layer deposition (ALD) in which the supply of the boron-containing gas and the supply of the first nitriding gas are alternately repeated.

5. The film-forming method according to claim 1, wherein,
a) includes forming the first film by exposing the substrate to a plasma generated from a hydrogen gas at either or both of:
after the supply of the boron-containing gas yet before the supply of the first nitriding gas; and
after the supply of the first nitriding gas yet before the supply of the boron-containing gas.

6. The film-forming method according to claim 1, wherein,
b) includes forming the second film through plasma atomic layer deposition (ALD) in which the supply of the silicon-containing gas and exposure of the substrate to a plasma generated from the second nitriding gas are alternately repeated.

7. The film-forming method according to claim 1, wherein,
the silicon-containing gas is a dichlorosilane gas.

8. The film-forming method according to claim 1, wherein,
the second nitriding gas is the same gas as the first nitriding gas.

9. The film-forming method according to claim 1, wherein,
the metal film is a ruthenium film.

10. The film-forming method according to claim 2, wherein,
the metal film is a ruthenium film.

11. The film-forming method according to claim 3, wherein,
the metal film is a ruthenium film.

12. The film-forming method according to claim 4, wherein,
the metal film is a ruthenium film.

13. The film-forming method according to claim 5, wherein,
the metal film is a ruthenium film.

14. The film-forming method according to claim 6, wherein,
the metal film is a ruthenium film.

15. The film-forming method according to claim 7, wherein,
the metal film is a ruthenium film.

16. The film-forming method according to claim 8, wherein,
the metal film is a ruthenium film.

17. A film-forming apparatus configured to form a film containing a silicon atom and a nitrogen atom on a surface of a substrate including a metal film at the surface of the substrate, the film-forming apparatus comprising:
a process chamber configured to house the substrate;
a gas supply configured to supply gas into the process chamber; and
a controller, wherein
the controller includes
a processor, and
a memory storing one or more programs, which when executed, cause the process to
supply a boron-containing gas and a first nitriding gas to the substrate, thereby forming a first film on the surface, the first film containing a boron atom and a nitrogen atom, and
supply a silicon-containing gas and a second nitriding gas to the substrate, thereby forming a second film on the first film, the second film containing a silicon atom and a nitrogen atom.
